(19) United States
(12) Patent Application Publication
(10) Pub. No.: US 2008/0084737 A1
(43) Pub. Date: Apr. 10, 2008

(54) Method of achieving zero column leakage after erase in flash EPROM

(75) Inventors: Yuan Tang, San Jose, CA (US); Ding Mao, San Jose, CA (US)

Correspondence Address: DAVIS CHIN, 10281 WEST LINCOLN HIGHWAY, FRANKFORT, IL, 60423, US

(73) Assignee: Eon Silicon Solutions, Inc. USA

(21) Appl. No.: 11/478,516

(22) Filed: Jun. 30, 2006

(51) Int. Cl. G11C 16/04; G11C 11/34

(52) U.S. Cl. 365/185.3; 365/185.24; 365/185.19

(57) ABSTRACT

There is provided a method of correcting over-erased memory cells in a flash EPROM memory device so as to achieve zero column leakage after erase. A ground potential is applied to all of the word lines in the memory device. First positive pulse voltages are applied to each bit line on a bit line by bit line basis until the column leakage current in each bit line is reduced to a relatively small value. Thereafter, a positive bias voltage is applied to each word line in a first timed sequence on a word line by word line basis. Second positive pulse voltages are simultaneously applied to each bit line in a second timed sequence on a bit line by bit line basis when the positive bias voltage is being applied to a first word line until the column leakage current in the corresponding bit line is reduced to zero and is then repeated for each subsequent remaining word line.

### BACKGROUND OF THE INVENTION

1. Field of the Invention

This invention relates generally to non-volatile memory devices having a floating gate such as an array of flash electrically programmable read-only memory (EPROMs) devices. More particularly, the present invention relates to a new and novel method of achieving zero column leakage after erase in a flash EPROM.

2. Description of the Prior Art

As is generally well known in the art, non-volatile memory devices using a floating gate for the storage of charges thereon such as EPROMs (electrically programmable read-only memories), EEPROMs (electrically, erasable programmable read-only memories) or Flash EPROMs have emerged in recent years. In such a conventional Flash EPROM memory device, a plurality of such one-transistor memory may be formed on a P-type semiconductor substrate in which each cell is comprised of an n⁺ drain region and an n⁺ source region both formed integrally within the substrate. A relatively thin gate dielectric layer is interposed between a top surface of the substrate and a conductive polysilicon floating gate. A polysilicon control gate is insulatively supported above the floating gate by a second dielectric layer. A channel region in the substrate separates the drain and source regions.

As is also well known, the charge of the floating gate of the one-transistor cell is dependent upon the number of electrons contained in the floating gate. During the programming mode, electrons are added to the floating gate of the cell so as to increase its threshold voltage. The term “threshold” refers to a gate-to-source voltage that must be applied between the gate and the source of the cell in order to cause it to conduct. During the erase mode, electrons are removed from the floating gate of the cell so as to decrease its threshold voltage. In programmed state, the threshold voltage of a cell is typically set at greater than +6.5 volts, while the threshold voltage of a cell in an erased state is typically limited below +3.0 volts.

In order to determine whether the cell has been programmed or not, the cell is read by applying a small positive voltage to the control gate between the +3.0 and +6.5 volt range, typically +5.0 volts, with the source region held at a ground potential (0 volts) and the drain held at a potential between +1 to +2 volts. If the transistor cell conducts or is turned-on, a current will flow through the transistor representing a “1” bit or erased state. On the other hand, if the transistor cell does not conduct or is turned-off no current will flow through the transistor representing a “” bit or programmed state.

The threshold voltage of each single-transistor flash EPROM cell after erase in the flash memory is variable. A large variation or wide distribution of the threshold voltages V_{T} after erasure is one of the major problems that has been encountered in the performance of EPROM devices. The distribution of the threshold voltages V_{T} among the individual cells in the EPROM array having floating-gate memory cells arrayed in rows and columns is caused by process variations, including local variations in the tunnel oxide thickness, the area of tunneling region, and the capacitive coupling ratio between the control gates and the floating gates as well as variations in the strengths of the erasing pulses.

If an unprogrammed flash EPROM cell in the array of such cells is repeatedly erased, the floating gate will eventually acquire a more positive potential so that the erase threshold voltage V_{T} on a given column (bit line) will be less than zero. As a result, even with the control gate being grounded, the cell will be conductive which causes column leakage so as to prevent the proper reading of any other cell in the column of the array containing this cell as well as making programming of other cells in the same column increasingly more difficult. This condition is generally referred to as “bit over-erase” which is disadvantageous since the data programming characteristics of the memory cell is deteriorated so as to cause endurance failures.

There have been various techniques developed in the prior art of correcting the problem of over-erased cells, but they all generally suffer from a number of drawbacks or introduce other problems. One such conventional correction technique for correcting over-erased bits in an array of flash EPROM memory cells is illustrated in FIG. 1. As can be seen, a flash EPROM array 10 is formed of a plurality of memory cells MC11 through MCnm arrayed in an n×m matrix on a single integrated circuit chip.

Each of the memory cells is comprised of one of the array core transistors Q_{P11} through Q_{Pnm} which function as a memory transistor for storing data “1” or “” therein. Each of the core transistors has its drain connected to one of the plurality of bit lines BL-BLm. All of the sources of the array core transistors are connected to a common array ground potential VSS. Each of the core transistors also has its control gate connected to one of the plurality of word lines WL-WLn.

In order to determine the state of a selected memory core cell, a sense amplifier SA1 functioning as a comparator receives a core current signal from a bit line on its one input and receives a reference current signal from a reference line on its other input. In this manner, the core current signal corresponding to a core current ICOR is compared with the reference current signal corresponding to a reference current IREF from a reference cell. The result on the output of the comparator indicates whether the selected memory core cell is storing a “1” or “0”.

After the flash memory array 10 has been erased, the prior art correction technique of correcting the over-erased bits is performed on the array columns detected to have column leakage indicative of an over-erased bit. Assume that the column or bit line BL1 was detected to contain an over-erased bit. Then voltage pulses having a magnitude of approximately 3-5 volts and a width of approximately 100 μS are applied to the bit line BL1 with the column leakage occurring while all of the word lines WL1-WLn, the common sources, and the substrate are grounded until the common leakage current is reduced.

This prior art over-erase correction (OEC) technique is only effective if the distribution of the erased threshold voltages V_{T} is similar to the one illustrated in FIG. 2. The graph of FIG. 2 shows a threshold voltage distribution for the Flash EPROM array having few over-erased cells with a very negative V_{T} (between −1 volts to 0 volts). The horizontal axis is the threshold voltage in volts, and the vertical axis represents the number of cells. Therefore, the curve 12 represents a plot of the number of cells in the array having a particular threshold voltage V_{T}. It will be noted that most of the cells have not been over-erased and thus have a positive threshold voltage and that only few cells have a negative threshold voltage. Further, the X's represent a few scattered well over-erased cells. As a result, the application of the prior art OEC method will produce a threshold voltage distribution curve 14 of FIG. 3, where the well over-erase cells represented by the X's in FIG. 2 have been corrected leaving cells with slightly negative threshold voltage V_{T} uncorrected.

FIG. 3 shows that this prior art OEC method suffers from the drawback of being ineffective in bringing back over-erased cells having a slightly negative voltage V_{T}, also as depicted in FIG. 4, to a slightly positive value. As can be seen, the curve 16 represents a distribution where numerous cells have a slightly negative threshold voltage V_{T} (just slightly below 0 volts). While each cell may contribute only 1 μA of column leakage current, these cells together in the array will have hundreds of microamps of leakage current so as to be harmful as the core cell current and operating voltage becomes smaller. Consequently, the prior art OEC method will be unable to reduce this column leakage current to zero since all of the leaky bits have a threshold voltage slightly below 0 volts.

Accordingly, there has arisen a need to provide a new and novel method for correcting or bringing back over-erased memory cells having either a very negative threshold voltage or a slightly negative threshold voltage to a positive value in an array of flash EPROM memory cells so as to achieve zero column leakage after erase. The present invention represents a significant improvement over the aforementioned prior art OEC method of FIG. 1.

### SUMMARY OF THE INVENTION

Accordingly, it is a general object of the present invention to provide a method for correcting over-erased memory cells in an array of flash EPROM memory cells so as to achieve zero column leakage after erase on an efficient and effective basis.

It is an object of the present invention to provide a method for correcting over-erased memory cells having both a very negative threshold voltage and a slightly negative threshold voltage to a positive value in an array of flash EPROM memory cells so as to achieve zero column leakage after erase.

It is another object of the present invention to provide a method for correcting over-erased memory cells in an array of flash EPROM memory cells so as to achieve zero column leakage after an erase operation which includes applying OEC steps and then applying POEC steps.

It is still another object of the present invention to provide a method for correcting over-erased memory cells in an array of flash EPROM memory cells so as to achieve zero column leakage after an erase operation which has a narrow threshold voltage distribution.

In accordance with these aims and objectives, the present invention is concerned with the provision of a method of correcting over-erased memory cells in a flash EPROM memory device so as to achieve zero column leakage after erase. A ground potential is applied to all of the word lines in the memory device. First positive pulse voltages are applied to each bit line on a bit line by bit line basis until the column leakage current in each bit line is reduced to a relatively small value.

Thereafter, a positive bias voltage is applied to each word line in a first timed sequence on a word line by word line basis. Second positive pulse voltages are simultaneously applied to each bit line in a second timed sequence on a bit line by bit line basis when the positive bias voltage is being applied to a first word line until the column leakage current in the corresponding bit line is reduced to zero and is then repeated for each subsequent remaining word line.

### BRIEF DESCRIPTION OF THE DRAWINGS

These and other objects and advantages of the present invention will become more fully apparent from the following detailed description when read in conjunction with the accompanying drawings with like reference numerals indicating corresponding parts throughout, wherein:

FIG. 1 is a schematic circuit diagram of a portion of a memory device having a flash EPROM memory array 10 to which a conventional OEC method is applied after erase;

FIG. 2 is a graph of a threshold voltage distribution for a flash EPROM memory array after erase with very negative threshold voltages;

FIG. 3 is a graph of a threshold voltage distribution for a flash EPROM memory array after the conventional OEC method of FIG. 1 has been employed;

FIG. 4 is a graph of a threshold voltage distribution for a flash EPROM memory array after erase with numerous cells having slightly negative threshold voltages;

FIG. 5 is a schematic circuit diagram of a portion of a memory device having a flash EPROM memory array 110 to which the improved over-erase correction method of the present invention is applied after erase;

FIG. 6 is a flow chart of the over-erase correction method in accordance with the present invention;

FIG. 7 is a flow chart of the block 612 of FIG. 6;

FIG. 8 is a flow chart of the block 616 of FIG. 6; and

FIG. 9 is a graph of a threshold voltage distribution for a flash EPROM memory array after the OEC and POEC steps in FIG. 6 of the present invention have been employed.

### DESCRIPTION OF THE PREFERRED EMBODIMENT

A new and novel method for correcting over-erased memory cells in an array of flash EPROM memory cells fabricated on a semiconductor integrated circuit substrate so as to achieve zero column leakage is described. In the following description, numerous specific details are set forth, such as specific circuit configurations, components, and the like in order to provide a thorough understanding of the present invention. However, it should be apparent to those skilled in the art that the present invention may be practiced without these specific details. In other instances, well-known processes, circuits and control lines, not particularly relevant to the understanding of the operating principles of the present invention, have been purposely omitted for the sake of clarity.

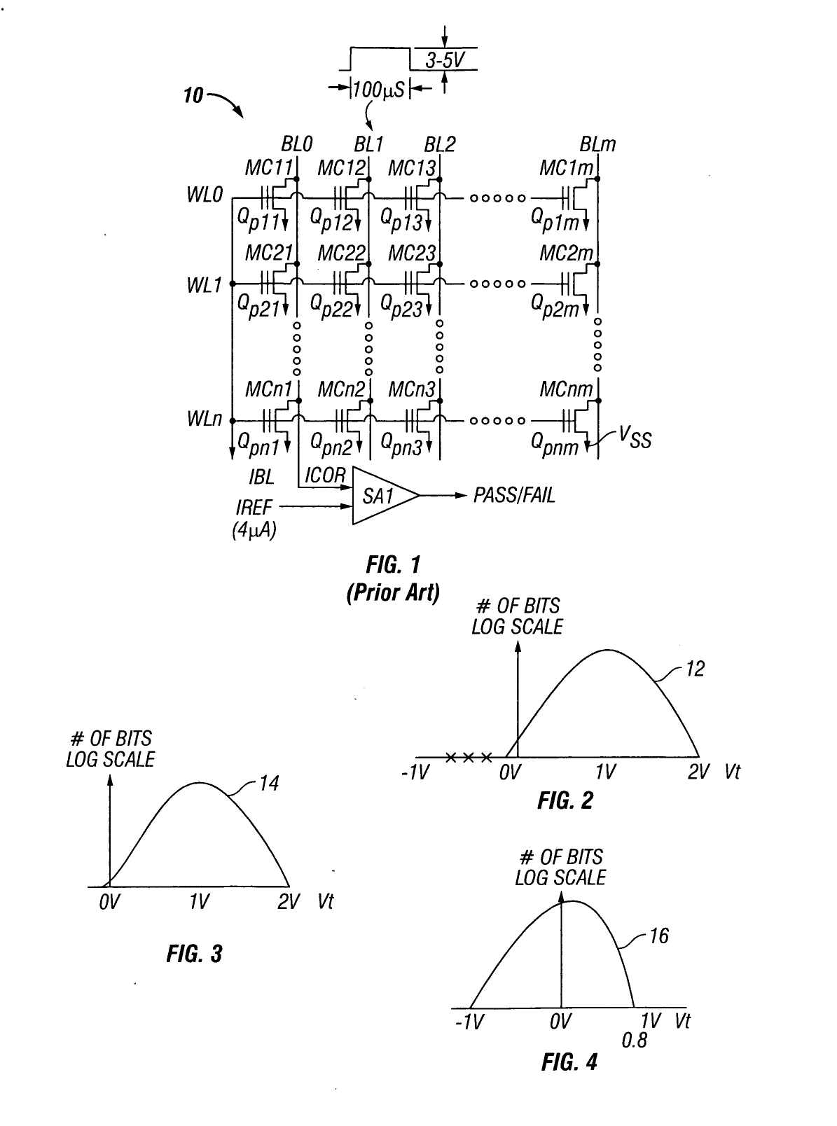

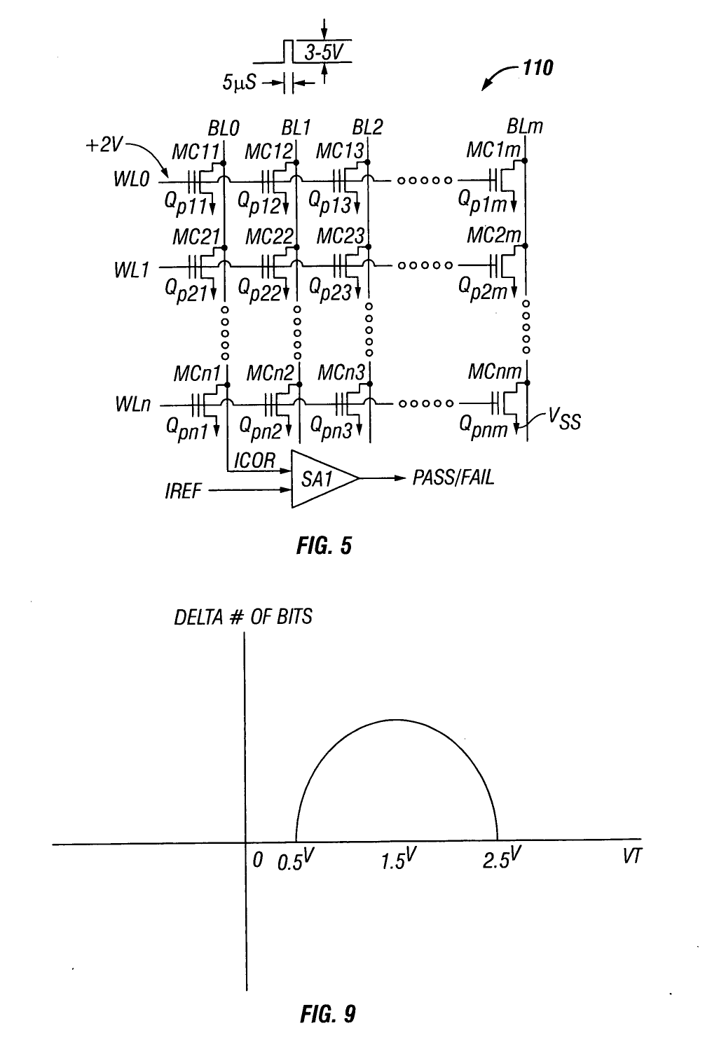

Referring now in detail to the drawings, there is shown in FIG. 5 a schematic circuit diagram of a portion of a semiconductor integrated circuit memory device having a flash EPROM memory array 110 to which a new and novel over-erase correction method of the present invention is applied after erase so as to achieve zero column leakage. Unlike the traditional prior art OEC method used in FIG. 1, the over-erase correction method of the present invention is capable of correcting or bringing back both cells with very negative threshold voltages and cells with slightly negative threshold voltages to a positive threshold voltage on an efficient and effective basis. After the present over-erase correction method is applied to the flash EPROM memory array 110 as illustrated in FIG. 5, there is obtained zero column leakage currents in the bit lines which was not achievable by the conventional OEC method of FIG. 1.

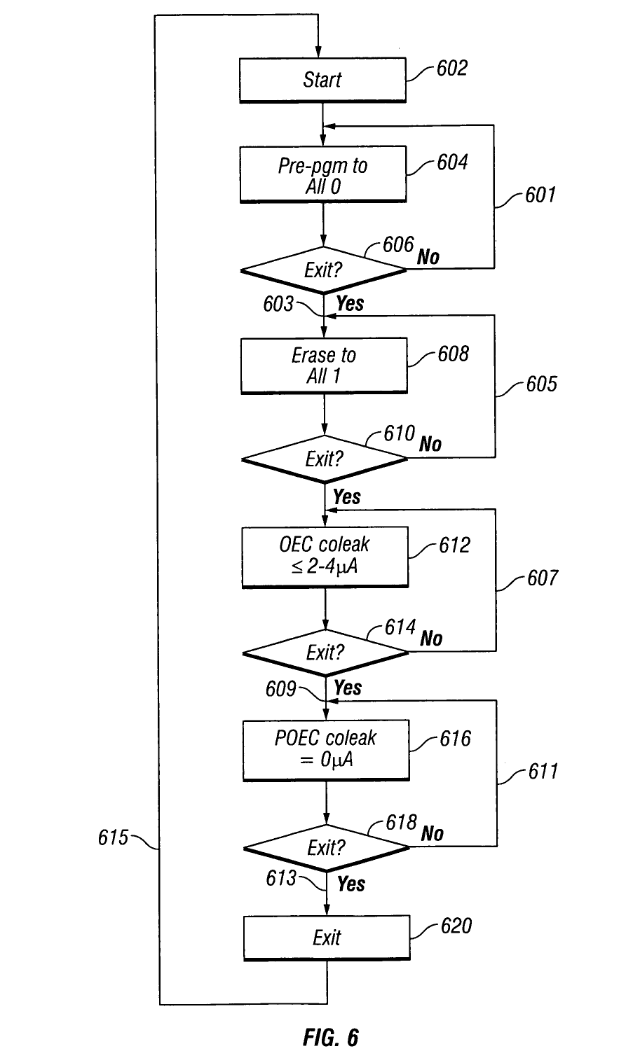

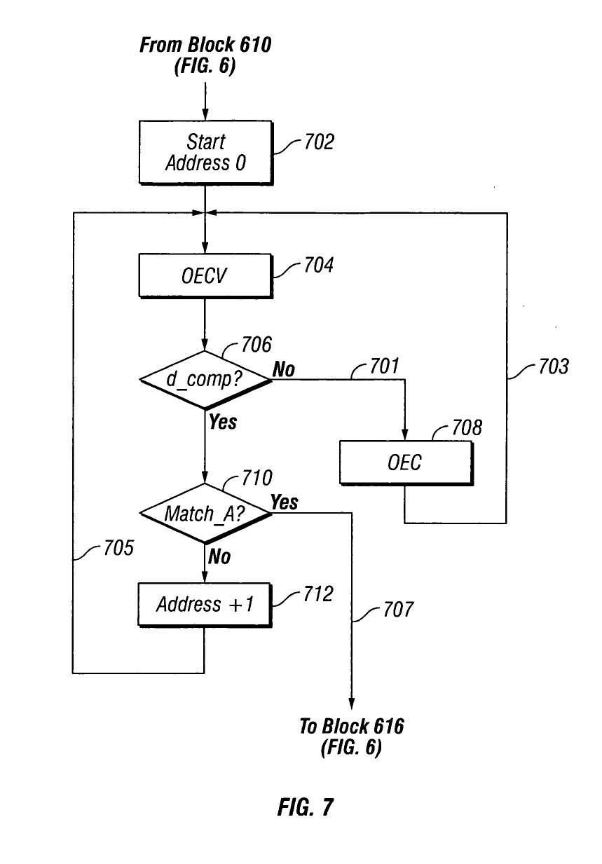

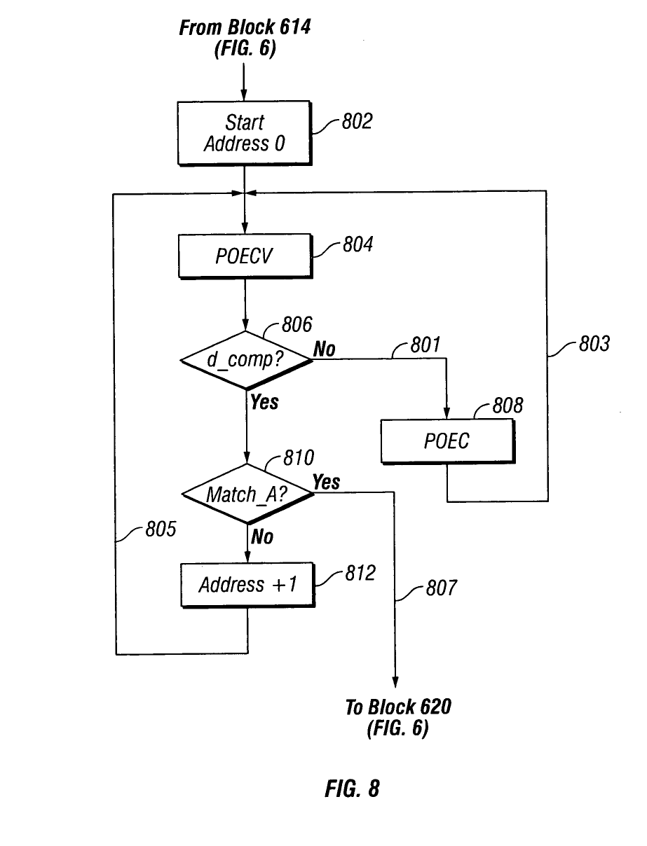

It will be recalled from FIG. 3 that while substantially all of the cells have a positive voltage threshold V_{T} after the prior art OEC method was applied there will still be some remaining cells with a small negative V_{T}. On the other hand, after the POEC steps of the present over-erase correction method are applied all of the cells will have a positive threshold voltage V_{T}. In particular, there is illustrated in FIG. 9 a graph of a threshold voltage distribution for the flash EPROM memory cell 110 after the OEC and POEC steps in FIG. 6 of the present invention have been employed, depicting all of the cells with a positive V_{T}.

The flash EPROM memory array 110 is formed of a plurality of memory cells MC11 through MCnm arranged in an n×m matrix on a single semiconductor substrate by known CMOS integrated circuit technology. It should be noted that the structural circuit components and their interconnection of the memory array 110 of FIG. 5 is identical to the memory array 10 of FIG. 1.

In particular, the memory cells MC11 through MC1m are arranged in the same row and have their selection terminals connected to the common word line WL. Similarly, the cells MC21 through MC2m are arranged in the same row and have their selection terminals connected to the common word line WL1. This is likewise done for each of the remaining rows in the array 110. Thus, the memory cells MCn1 through MCnm are arranged on the same row and have their selection terminals connected to the common word line WLn. Furthermore, the memory cells MC11 through MCn1 are arranged in the same column and have their data terminals connected to the common bit line BL0. Similarly, the cells MC12 through MCn2 are arranged in the same column and have their data terminals connected to the common bit lines BL1. This is likewise done for each of the remaining columns in the array 110. Thus, the memory cells MC1m through MCnm are arranged in the same column and have their data terminals connected to the common bit line BLm.

Each of the memory cells MC11 through MCnm is comprised of one of the corresponding floating gate array transistors Q_{P11} through Q_{Pnm}. The array transistors Q_{P11} through Q_{Pnm} function as a memory transistor for storing data “1” or “0” therein. Each of the array transistors Q_{P11}-Q_{Pnm} has its gate connected to one of the rows of word lines WL-WLn, its drain connected to one of the columns of bit lines BL-BLm, and its source connected to an array ground potential VSS.

The improved over-erase correction process or method for achieving zero column leakage of the present invention for use in the memory array 110 of FIG. 5 will now be explained with reference to FIGS. 6 through 8. Initially, it is assumed that the V_{T} distribution after erase is similar to the one illustrated in FIG. 4, where there exists numerous over-erased cells having slightly negative V_{T}. As will be recalled, this is the type of distribution where application of the conventional prior art OEC method to the memory array would be ineffective in reducing the column leakage current to zero.

In FIG. 6, the present over-erase correction process is started in block 602 and proceeds to block 604 where all of the memory cells in the array 110 are pre-programmed to a “0” state. In decision block 606, the pre-programming operation is caused to continue in the block 604 via line 601 until all of the memory cells are programmed to “0”. When this occurs, the process proceeds to block 608 via line 603 where all of the memory cells are erased to a “1” state. In decision block 610, the erasing operation is caused to continue in the block 608 via line 605 until all of the memory cells are erased to “1”. When this happens, the process goes to block 612 where the conventional OEC method steps, as was previously discussed with respect to FIG. 1, are performed so to correct the column leakage to a relatively low, non-zero level (e.g., 2-4 uA).

In decision block 614, the conventional OEC method steps are caused to continue in the block 612 via line 607 until all of the columns have a leakage current less than or equal to about 2-4 uA. When this is reached, the process goes to block 616 via line 609 where the program-over-erase correction (POEC) method steps of the present invention are performed so as to further reduce the residue column leakage current to a zero value. In decision block 618, the POEC method steps are caused to continue in the block 616 via line 611 until the leakage current in each of the columns is equal to zero uA. When this occurs, the process is completed and proceeds to block 620 via line 613. The present over-erase correction method can be then repeated via line 615.

With particular reference again to the memory array of FIG. 1 and the flow chart of FIG. 7, the conventional OEC method steps in block 612 will now be explained. In FIG. 7, the conventional OEC process is started in block 702 and proceeds to OECV block 704 where the conventional over-erase-correction verify mode of operation is performed. In FIG. 1, it will noted that all of the word lines WL0-WLn and the sources of the array transistors as well as the substrates are tied to the array ground potential VSS, which is at 0 volts. Then, a bias voltage of +1V is applied to a first selected bit line BL0.

In decision block 706, a sense amplifier SA1 functioning as a comparator receives a reference current IREF on its one input and receives a bit line current IBL on its other input. The result on the output of the SA1 indicates whether the selected bit line or column has passed or failed. If there is a failure indicative of an over-erased bit, the process goes to OEC block 708 via line 701 where a voltage pulse having a magnitude of approximately +3.0-+5.0 volts and a width of about 100 uS is applied to the selected bit line BL0 with the column leakage. Then, the process will go back to the OECV block 704 via line 703 where the over-erase-correction verify mode of operation will be repeated. This is continued until the column leakage current is reduced to about 2-4 uA. When this occurs, the process goes to decision block 710 to determine if all of the columns have been OEC verified. If not, then in the block 712 the address is increased by 1 and the next column in sequence (BL1, BL2, and so on) is OEC verified by the block 704 via line 705. When all of the columns have been OEC verified, the process goes to the block 616 of FIG. 6 via line 707.

With particular reference again to the memory array of FIG. 5 and the flow chart of FIG. 8, the present POEC method steps will now be explained. In FIG. 8, the POEC process is started in block 802 and proceeds to POECV block 804 where the program-over-erase-correction verify mode of operation is performed. In FIG. 5, it will noted that each of the word lines WLO-WLn has a bias voltage of +5.0 volts applied sequentially thereto in a first timed sequence manner (word line by word line) while all of the remaining non-selected word lines WL1-WLn and the sources of the array transistors as well as the substrates are tied to the array ground potential VSS, which is at 0 volts. Simultaneously, as the bias voltage is being applied to the first word line WL0 a bias voltage of +1V is applied sequentially to each bit line BL0-BLm in a second timed sequence manner (bit line by bit line).

In decision block 806, a sense amplifier SA1 functioning as a comparator receives a reference current IREF on its one input and receives a core cell current ICOR on its other input. The result on the output of the SA1 indicates whether the selected core cell has passed or failed. If there is a failure indicative of an over-erased bit, the process goes to POEC block 808 via line 801 where a positive bias voltage having a magnitude of about +2.0 volts is applied to each word line in a third timed sequence on a word line by word line basis and where simultaneously a voltage pulse having a magnitude of approximately +3.0-+5.0 volts and a width of about 10 uS is applied to each bit line in a fourth timed sequence on a bit line by bit line basis. Then, the process will go back to the POECV block 804 via line 803 where the over-erase-correction verify mode of operation will be repeated. This is continued until the leakage current is reduced to zero uA. When this occurs, the process goes to decision block 810 to determine if all of the core cells in all of the word lines have been POEC verified. If not, then in the block 812 the address is increased by 1 and the next word line in sequence (WL1, WL2, and so on) is POEC verified by the block 804 via line 805. When the core cells in all of the word lines have been POEC verified, the process goes to the block 620 of FIG. 6 via line 807.

It should be clear to those skilled in the art that the present over-erase correction method utilizes in general a two-stage approach. The first stage of the novel present method is to use the conventional OEC method steps to correct the column leakage current to a relatively small, non-zero value. The second stage of the new method is to use the POEC method steps to further correct the residue column leakage current to zero. It will be noted that if only the first stage is used, the column leakage current will not be corrected to zero within a reasonable amount of time. This is because the correction speed slows down when the threshold V_{T} is increased close to 0 volts since the electron injection efficiency onto the floating gate will decrease exponentially with (VG−VT). Further, since a threshold V_{T} close to zero corresponds to a very small current (e.g., less than 1 uA) under the conventional OEC verify mode of operation in which VG=0V, it will be difficult to reliably sense due to the small signal-to-noise ratio.

On the other hand, if only the second stage is used a selected memory core cell that does not need correction can be falsely corrected due to a leaky cell in the same column. This is because when the selected memory cell (good cell) is POEC verified the current from the leaky cell will be added to the current of the selected memory cell so as to increase the total current to a level indicative of a bad cell (one that needs correction). However, after the leaky cell is corrected later on so that the column leakage current is removed, the selected memory cell that was corrected initially will have a V_{T} which will be too high. Thus, the selected memory cell was falsely corrected. In order to avoid this kind of false correction, the conventional OEC method must be applied first so as to reduce the column leakage current to about 2-4 uA. Thereafter, the POEC method is applied so as to further reduced the column leakage current to zero uA.

From the foregoing detailed description, it can thus be seen that the present invention provides a method of correcting over-erased memory cells in a flash EPROM memory device after erase so as to achieve zero column leakage. The correction method of the present invention is achieved by applying first positive pulse voltages to each bit line on a bit line by bit line basis until the column leakage current in each bit line is reduced to a relatively small value. Thereafter, a positive bias voltage is applied to each word line in a first timed sequence on a word line by word line basis. Second positive pulse voltages are simultaneously applied to each bit line in a second timed sequence on a bit line by bit line basis when the positive bias voltage is being applied to a first word line until the column leakage current in the corresponding bit line is reduced to zero and is then repeated for each subsequent remaining word line.

While there has been illustrated and described what is at present considered to be a preferred embodiment of the present invention, it will be understood by those skilled in the art that various changes and modifications may be made, and equivalents may be substituted for elements thereof without departing from the true scope of the invention. In addition, many modifications may be made to adapt a particular situation or material to the teachings of the invention without departing from the central scope thereof. Therefore, it is intended that this invention not be limited to the particular embodiment disclosed as the best mode contemplated for carrying out the invention, but that the invention will include all embodiments falling within the scope of the appended claims.

1. In a semiconductor integrated circuit memory device having a correction structure for performing a correction operation on overerased memory cells in the memory device so as to achieve zero column leakage after erase, said correction structure comprising, in combination:
a cell matrix having a plurality of memory cells arranged in rows of word lines and columns of bit lines intersecting said rows of word line, each of said memory cells including a floating gate array transistor having its control gate connected to one of said rows of word lines, its drain connected to one of said columns of bit lines, and its source and substrate connected to a ground potential;
means for applying a ground potential to all of the word lines in the memory device;
means for applying first positive pulse voltages to each bit line on a bit line by bit line basis until the column leakage current in each bit line is reduced to a relatively small value;
each of said first positive pulse voltages having a magnitude in the range of approximately +3.0 to +5.0 volts and a width of about 5-10 μS;
means for applying thereafter a positive bias voltage to each word line in a first timed sequence on a word line by word line basis;
said positive bias voltage having a magnitude in the range of about +2.0 to +5.0 volts;
means for simultaneously applying second positive pulse voltages to each bit line in a second timed sequence on a bit line by bit line basis when said positive bias voltage is being applied to a first word line until the column leakage current in the corresponding bit line is reduced to zero and is then repeated for each subsequent remaining word line; and
each of said second positive pulse voltages having a magnitude in the range of +3.0 to +5.0 volts and a width of about 2 μS.

2-5. (canceled)

6. In a semiconductor integrated circuit memory device as claimed in claim 1, wherein said overerased cells have threshold voltages which are only slightly negative.

7-8. (canceled)

9. In a semiconductor integrated circuit memory device as claimed in claim 1, wherein the small value of column leakage current is about 2-4 μA.

10. A method of correcting overerased memory cells in a flash EPROM memory device so as to achieve zero column leakage after erase, said memory device including an array of memory cells in which each cell has a control gate, floating gate, drain, source and substrate, said memory cells being arranged in rows of word lines and columns of bit lines intersecting said rows of word lines, said method comprising the steps of:
applying a ground potential to all of the word lines in the memory device;
applying first positive pulse voltages having a magnitude in the range of approximately +3.0 to +5.0 volts and a width of about 5-10 μS to each bit line on a bit line by bit line basis until the column leakage current in each bit line is reduced to a relatively small value;
applying thereafter a positive bias voltage having a magnitude in the range of about +2.0 to +5.0 volts to each word line in a first timed sequence on a word line by word line basis; and
simultaneously applying second positive pulse voltages having a magnitude in the range of +3.0 to +5.0 volts and a width of about 2 μS to each bit line in a second timed sequence on a bit line by bit line basis when said positive bias voltage is being applied to a first word line until the column leakage current in the corresponding bit line is reduced to zero and is then repeated for each subsequent remaining word line.

11-14. (canceled)

15. A method of correcting over-erased memory cells as claimed in claim 10, wherein said over erased cells have threshold voltages which are only slightly negative.

16-17. (canceled)

18. A method of correcting over-erased memory cells as claimed in claim 10, wherein the small value of column leakage current is about 2-4 μA.

19. (canceled)
